(19) United States
(12) Patent Application Publication
(10) Pub. No.: US 2026/0113964 A1
(43) Pub. Date: Apr. 23, 2026

(54) METHOD OF MANUFACTURING SEMICONDUCTOR DEVICE INCLUDING TWO-DIMENSIONAL MATERIALS

(71) Applicant: SAMSUNG ELECTRONICS CO., LTD., Suwon-si (KR)

(72) Inventors: Seungjun LEE, Suwon-si (KR); Minwoo Park, Suwon-si (KR); Joungeun Yoo, Suwon-si (KR); Eunkyu Lee, Suwon-si (KR); Seongjune Jeong, Suwon-si (KR); Hanbyul Kang, Suwon-si (KR); Jaeho Kim, Suwon-si (KR); Minseok Yoo, Suwon-si (KR)

(73) Assignee: SAMSUNG ELECTRONICS CO., LTD., Suwon-si (KR)

(21) Appl. No.: 19/357,760

(22) Filed: Oct. 14, 2025

(30) Foreign Application Priority Data
Oct. 22, 2024 (KR) 10-2024-0145121

(51) Int. Cl. H10D 30/01; H01J 37/32; H01L 21/465; H10D 62/80

(52) U.S. Cl. CPC H10D 30/017; H01J 37/32449; H01J 37/32541; H10D 62/883; H10P 50/20; H10P 52/00; H10P 95/70; H01J 37/32192; H01J 2237/327; H01J 2237/335

(57) ABSTRACT

A method of manufacturing a semiconductor device is provided. The method includes: providing a two-dimensional material layer on a substrate; and supplying an etchant to the two-dimensional material layer to remove a residue from the two-dimensional material layer. The supplying the etchant to the two-dimensional material layer includes: supplying a first process gas to a chamber in which the substrate is provided; supplying microwaves to the chamber to form a first plasma in the chamber; and supplying a second process gas, including a different material from the first process gas, to the chamber to form a second plasma including the etchant.

### CROSS-REFERENCE TO RELATED APPLICATION

This application claims priority to Korean Patent Application No. 10-2024-0145121, filed on Oct. 22, 2024, in the Korean Intellectual Property Office, the disclosure of which is incorporated by reference herein in its entirety.

### BACKGROUND

The present disclosure relates to a method of manufacturing a semiconductor device including two-dimensional materials.

Two-dimensional materials include atoms that form a specific crystal structure. Research and development have been conducted on various two-dimensional materials having semiconductor or insulator properties. These two-dimensional materials have attracted attention as next-generation materials that may overcome limitations of related devices.

To grow two-dimensional materials with high quality and uniform thickness on a wafer scale, a metal organic precursor may be introduced. However, when patterning two-dimensional materials on a wafer, there are process issues such as a decrease in the quality of the thin film and the need for complex processes in multiple operations.

### SUMMARY

One or more example embodiments provide a method of manufacturing a semiconductor device including supplying an etchant to a chamber using surface wave plasma to remove a residue from a two-dimensional material layer.

According to an aspect of an example embodiment, a method of manufacturing a semiconductor device includes: providing a two-dimensional material layer on a substrate; and supplying an etchant to the two-dimensional material layer to remove a residue from the two-dimensional material layer. The supplying the etchant to the two-dimensional material layer includes: supplying a first process gas to a chamber in which the substrate is provided; supplying microwaves to the chamber to form a first plasma in the chamber; and supplying a second process gas, including a different material from the first process gas, to the chamber to form a second plasma including the etchant.

According to another aspect of an example embodiment, a method of manufacturing a semiconductor device includes: providing a two-dimensional material layer on a substrate; forming a mask layer on the two-dimensional material layer, wherein the mask layer exposes a first region and a second region of the two-dimensional material layer; forming a first source/drain electrode on the first region and a second source/drain electrode on the second region; removing the mask layer to expose a third region of the two-dimensional material layer between the first region and the second region; and removing a residue on the third region of the two-dimensional material layer. The removing the residue includes: supplying a first process gas to a chamber in which the substrate is provided; supplying microwaves to the chamber to form a first plasma in the chamber; and supplying a second process gas, including a different material from the first process gas, to the chamber to form a second plasma.

According to another aspect of an example embodiment, a method of manufacturing a semiconductor device includes: providing a two-dimensional material layer on a substrate; and supplying an etchant to the two-dimensional material layer to remove a residue from the two-dimensional material layer. The supplying the etchant to the two-dimensional material layer includes: supplying a first process gas to a chamber in which the substrate is provided; supplying microwaves to the chamber to form a first plasma in the chamber; and supplying a second process gas, including a different material from the first process gas, to the chamber to form a second plasma. The second process gas includes hydrogen. The second plasma includes the etchant. The etchant includes hydrogen radicals. The residue is removed from a surface of the two-dimensional material layer by the hydrogen radicals.

According to one or more example embodiments, because residues are removed using surface wave plasma, damage to the two-dimensional material layer may be prevented or reduced. Additionally, because plasma is formed in a chamber, the process time may be shortened.

Advantages and effects are not limited to the foregoing, and may be more easily understood in view of the following description of example embodiments.

### BRIEF DESCRIPTION OF DRAWINGS

The patent or application file contains at least one drawing executed in color. Copies of this patent or patent application publication with color drawing(s) will be provided by the Office upon request and payment of the necessary fee.

The above and other aspects, features, and advantages will be more apparent from the following description of example embodiments, taken in conjunction with the accompanying drawings, in which:

FIG. 1 is a flowchart illustrating a method of manufacturing a semiconductor device according to an example embodiment;

FIGS. 2A, 2B, 2C, 2D, 2E and 2F are vertical cross-sectional views illustrating a method of manufacturing a semiconductor device according to an example embodiment;

FIG. 3 is a flowchart illustrating a method of removing a residue according to an example embodiment;

FIG. 4A is a cross-sectional view of a plasma processing apparatus according to an example embodiment;

FIG. 4B is a cross-sectional view of the plasma processing apparatus according to an example embodiment;

FIG. 5 is a conceptual view illustrating a method for removing residues according to an example embodiment;

FIG. 6 is a cross-sectional view of a plasma processing apparatus according to an example embodiment;

FIGS. 7A and 7B illustrate Optical Emission Spectroscopy (OES) analysis results;

FIG. 8A illustrates a wafer map according to a change in pressure;

FIG. 8B illustrates a wafer map according to a change in flow rate;

FIGS. 9A, 9B and 9C are diagrams illustrating a result of measuring an electron temperature and a result of measuring an ion density;

FIGS. 10A and 10B illustrate surfaces of two-dimensional materials;

FIGS. 11A and 11B illustrate Raman spectra of two-dimensional materials.

### DETAILED DESCRIPTION

Hereinafter, example embodiments of the present disclosure will be described with reference to the accompanying drawings. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. It will be also understood that, even if a certain operation of manufacturing an apparatus or structure is described later than another operation, the operation may be performed later than the other operation unless the other operation is described as being performed after the operation. The same reference numerals are used to denote the same elements in the drawings, and repeated descriptions thereof will be omitted.

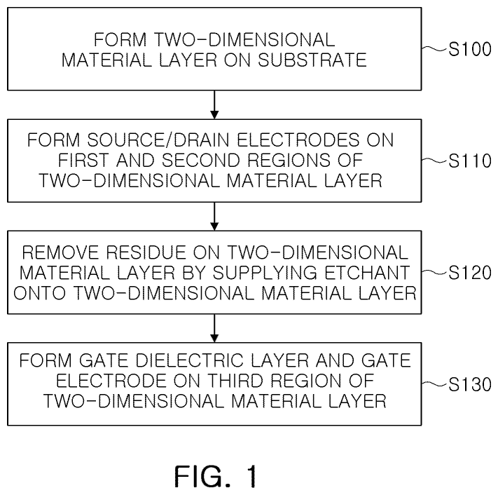

FIG. 1 is a flowchart illustrating a method of manufacturing a semiconductor device according to an example embodiment.

Referring to FIG. 1, a method of manufacturing semiconductor device according to an example embodiment may include forming a two-dimensional material layer on a substrate (S100), forming source/drain electrodes on first and second regions of the two-dimensional material layer (S110), removing a residue on the two-dimensional material layer by supplying an etchant to the two-dimensional material layer (S120), and forming a gate dielectric layer and a gate electrode on a third region of the two-dimensional material layer (S130).

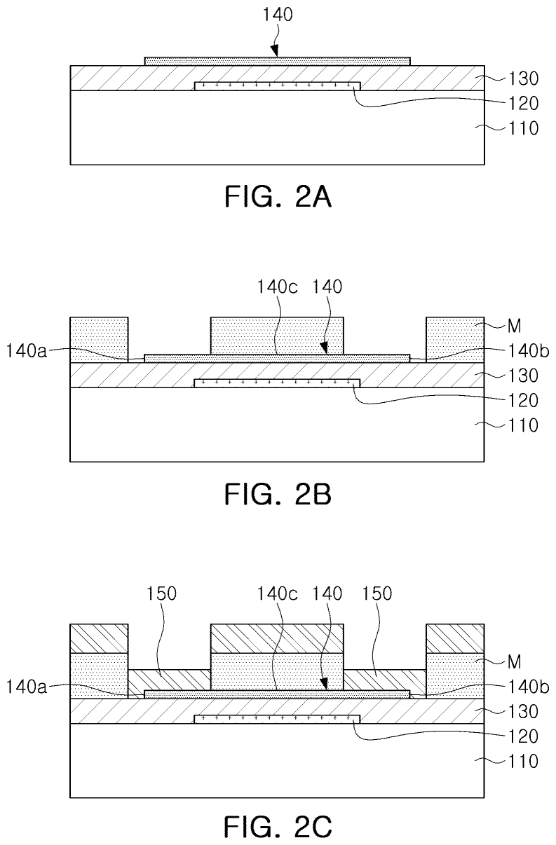

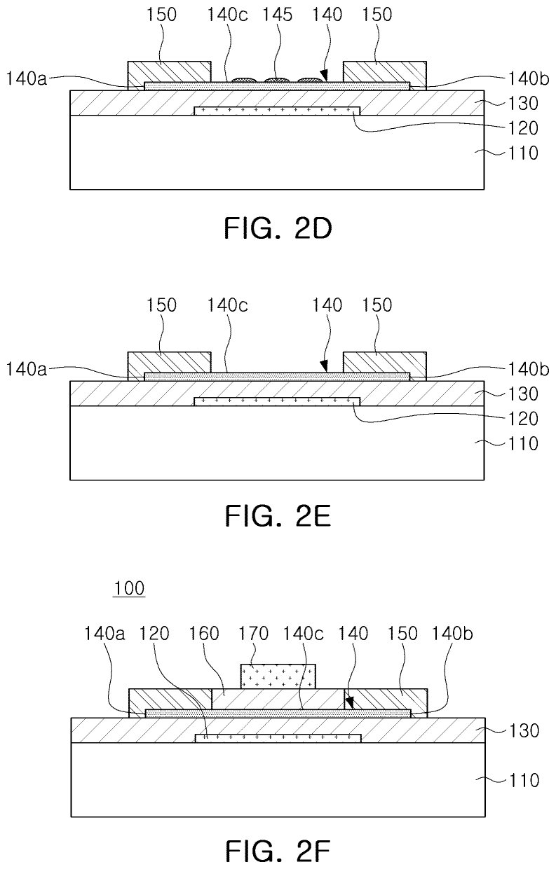

FIGS. 2A to 2F are vertical cross-sectional views illustrating a method of manufacturing a semiconductor device according to an example embodiment.

Referring to FIGS. 1 and 2A, a back gate electrode 120 and a back gate dielectric layer 130 may be formed on a substrate 110. The substrate 110 may be a semiconductor substrate, an insulating substrate, or a semiconductor substrate having an insulating layer formed on a surface, but is not limited thereto. The substrate 110 may include a semiconductor material, such as a group IV semiconductor, a group III-V compound semiconductor, or a group II-VI compound semiconductor. For example, the group IV semiconductor may include silicon, germanium, or silicon-germanium. For example, the substrate 110 may be a silicon substrate in which silicon oxide is formed on silicon.

The back gate electrode 120 may be disposed on the substrate 110, and the back gate dielectric layer 130 may cover the substrate 110 and the back gate electrode 120. The back gate electrode 120 may be disposed on an insulating layer of the substrate 110. According to an example embodiment, the back gate electrode 120 and the back gate dielectric layer 130 may be omitted.

The back gate electrode 120 may include a conductive material, and the conductive material may include at least one of a doped semiconductor material (e.g., doped silicon, doped germanium, etc.), a conductive metal nitride (e.g., titanium nitride, tantalum nitride, tungsten nitride, etc.), a conductive metal oxide (e.g., indium tin oxide (ITO), indium zinc oxide (IZO), etc.), a metal (e.g., tungsten, titanium, tantalum, cobalt, aluminum, ruthenium, etc.), and a metal-semiconductor compound (e.g., tungsten silicide, cobalt silicide, titanium silicide, etc.).

The back gate dielectric layer 130 may include at least one of a silicon oxide, a silicon nitride, a low-κ material, and a high-κ material. The high-κ material may refer to a dielectric material having a dielectric constant higher than that of silicon oxide, and the low-κ material may refer to a dielectric material having a dielectric constant lower than that of silicon oxide. The high-κ material may be, for example, a metal oxide or a metal oxynitride. The high-κ material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃). The back gate dielectric layer 130 may be formed as a single layer or multiple layers of the aforementioned materials.

A two-dimensional material layer 140 may be formed on a substrate 110 (S100). For example, the two-dimensional material layer 140 may be formed on the back gate dielectric layer 130. For example, the back gate electrode 120 and the back gate dielectric layer 130 may be omitted, and the two-dimensional material layer 140 may be formed on the substrate 110. The two-dimensional material layer 140 may include a two-dimensional material. The two-dimensional material layer 140 may be formed by a deposition process such as a chemical vapor deposition (CVD) method. For example, the two-dimensional material layer 140 may be formed by a CVD method using an organic ligand, such as Mo(CO)₆ and (C₂H₅)₂S₂, as a precursor.

The two-dimensional material refers to a semiconductor material having a two-dimensional crystal structure. The two-dimensional material may have a layered structure of a monolayer or a multilayer. Each layer included in the two-dimensional material may have a thickness on an atomic level. For example, thickness of each layer included in the two-dimensional material may correspond to a thickness of a single atom. The two-dimensional material may include, for example, a transition metal dichalcogenide (TMD).

The TMD may include, for example, one transition metal among Mo, W, Nb, V, Ta, Ti, Zr, Hf, Tc, and Re, and one chalcogen element among S, Se, and Te. The TMD may be expressed, for example, as MX₂, where M represents a transition metal and X represents a chalcogen element. For example, M may be Mo, W, Nb, V, Ta, Ti, Zr, Hf, Tc, Re, or the like, and X may be S, Se, Te, or the like. Accordingly, for example, the TMD may include MoS₂, MoSe₂, MoTe₂, WS₂, WSe₂, WTe₂, ZrS₂, ZrSe₂, HfS₂, HfSe₂, NbSe₂, and ReSe₂. Alternatively, the TMD may not be expressed as MX₂. In this case, for example, the TMD may include CuS, a compound of Cu, a transition metal, and S, a chalcogen element. On the other hand, the TMD may be a chalcogenide material including a non-transition metal. The non-transition metal may include, for example, Ga, In, Sn, Ge, Pb, etc. In this case, the TMD may include a compound of a non-transition metal such as Ga, In, Sn, Ge and Pb, and a chalcogen element such as S, Se and Te. For example, the TMD may include SnSe₂, GaS, GaSe, GaTe, GeSe, In₂Se₃, and InSnS₂.

As described above, the TMD may include one metal element among Mo, W, Nb, V, Ta, Ti, Zr, Hf, Tc, Re, Cu, Ga, In, Sn, Ge and Pb, and one chalcogen element among S, Se and Te. However, the materials described above are only examples, and other materials may be used as TMD materials.

The two-dimensional material layer 140 may further include a predetermined dopant to control the mobility of the two-dimensional semiconductor material. Specifically, the two-dimensional semiconductor material may be doped with a P-type dopant or an N-type dopant. The P-type dopant or the N-type dopant may be doped by ion implantation or chemical doping.

A source of the P-type dopant may include, for example, ionic liquids such as NO₂BF₄, NOBF₄ and NO₂SbF₆, acidic compounds such as HCl, H₂PO₄, CH₃COOH, H₂SO₄ and HNO₃, organic compounds such as dichlorodicyanoquinone (DDQ), oxone, dimyristoylphosphatidylinositol (DMPI), and trifluoromethanesulfoneimide. Alternatively, a source of the P-type dopant may include HPtCl₄, AuCl₃, HAuCl₄, silver trifluoromethanesulfonate (AgOTf), AgNO₃, H₂PdCl₆, Pd(OAc)₂, and Cu(CN)₂.

A source of the N-type dopant may include, for example, a reduction product of a substituted or unsubstituted nicotinamide; a reduction product of a compound which is chemically bound to a substituted or unsubstituted nicotinamide; and a compound including at least two pyridinium moieties in which a nitrogen atom of at least one of the pyridinium moieties is reduced. For example, the source of the N-type dopant may include nicotinamide mononucleotide-H (NMNH), nicotinamide adenine dinucleotide-H (NADH), nicotinamide adenine dinucleotide phosphate-H (NADPH), or a viologen. Alternatively, the source of the N-type dopant may include a polymer such as polyethylenimine (PEI). Alternatively, the N-type dopant may include an alkali metal such as K or Li. The P-type dopant and N-type dopant materials described above are provided as examples, and various other materials may be used as dopants.

Referring to FIG. 2B, the method may include forming a mask layer M on a two-dimensional material layer 140. The mask layer M may be formed to cover the back gate dielectric layer 130 and the two-dimensional material layer 140, and may be patterned to expose a portion of the two-dimensional material layer 140. The patterning process may include removing a portion of the mask layer M by a wet etching process. The portions of the two-dimensional material layer 140 exposed by the mask layer M may be referred to as a first region 140a and a second region 140b, respectively. A portion of the two-dimensional material layer 140 between the first region 140a and the second region 140b may be referred to as a third region 140c. The third region 140c may be covered with a mask layer M.

In an example embodiment, the mask layer M may include a CₓH_{y}O_{z}-based hydrocarbon material (wherein X, Y and Z are arbitrary integers). For example, the mask layer M may be a photoresist, and may include materials such as 2-heptanone, dihydro-2-furanone, and 1-Methoxy-2-propanol acetate.

Referring to FIGS. 1 and 2C, source/drain electrodes 150 may be formed on the first and second regions 140a and 140b of the two-dimensional material layer 140 (S110). The source/drain electrodes 150 may be formed by depositing a conductive material. The source/drain electrodes 150 may cover side surfaces and upper surfaces of the first and second regions 140a and 140b of the two-dimensional material layer 140, as well as a portion of the back gate dielectric layer 130 between the mask M and the two-dimensional material layer 140. A conductive material may also be deposited on an upper surface of the mask layer M.

The source/drain electrode 150 may include a conductive material, and the conductive material may include at least one of a doped semiconductor material, a conductive metal nitride, a conductive metal oxide, a metal, or a metal-semiconductor compound.

Referring to FIG. 2D, the conductive material on the upper surface of the mask layer M may be removed, and the mask layer M may be removed. For example, the mask layer M may be removed by a stripping process, and the third region 140c of the two-dimensional material layer 140 may be exposed.

In an example embodiment, a residue 145 may remain on the two-dimensional material layer 140. For example, the residue 145 may remain on the third region 140c of the two-dimensional material layer 140 after the mask layer M is removed. The residue 145 may be derived from the mask layer M and/or the two-dimensional material layer 140. For example, in a process of removing the mask layer M, a portion of the mask layer M may not be completely removed and may remain on the two-dimensional material layer 140. As another example, a precursor used when depositing the two-dimensional material layer 140 may remain on the two-dimensional material layer 140.

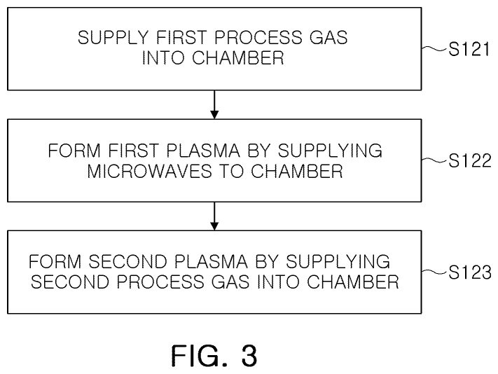

Referring to FIG. 1 and FIG. 2E, the residue 145 on the two-dimensional material layer 140 may be removed by supplying an etchant on the two-dimensional material layer 140 (S120). A method of supplying an etchant on the two-dimensional material layer 140 will be described in detail below with reference to FIGS. 3 to 5.

Referring to FIG. 1 and FIG. 2F, a gate dielectric layer 160 and a gate electrode 170 may be formed on the third region 140c of the two-dimensional material layer 140 (S130), and a semiconductor device 100 may be manufactured. A structure of the semiconductor device 100 illustrated in FIG. 2F is provided as an example and example embodiments are not limited thereto. According to an example embodiment, an upper surface of the gate dielectric layer 160 may cover upper surfaces of the source/drain electrodes 150 or may be disposed on a level higher than the upper surfaces of the source/drain electrodes 150.

The gate dielectric layer 160 may include at least one of silicon oxide, silicon nitride, a low-κ material, and a high-κ material. The gate electrode 170 may include a conductive material, and the conductive material may include at least one of a doped semiconductor material, a conductive metal nitride, a conductive metal oxide, a metal, and a metal-semiconductor compound.

The semiconductor device 100 may include, for example, a field effect transistor (FET). The first and second regions 140a and 140b of the two-dimensional material layer 140 may function as a source/drain of the transistor, and the third region 140c may function as a channel. The semiconductor device 100 may further include a peripheral circuit disposed on the substrate 110 and configured to select and control an impurity region due to doping, an electronic device such as a transistor, or memory cells for storing data.

In an example embodiment, the semiconductor device 100 may include a Fin Field Effect Transistor (FinFET) in which the third region 140c has a fin shape. In an example embodiment, the semiconductor device 100 may include a Multi-Bridge Channel (MBC) FET in which the gate electrode 170 surrounds the two-dimensional material layer 140 in a Gate all around (GAA) structure.

FIG. 3 is a flow chart illustrating a method of removing residue according to an example embodiment.

Referring to FIG. 3, a method (S120) of removing the residue 145 on the two-dimensional material layer 140 by supplying the etchant on the two-dimensional material layer 140 may include supplying a first process gas to a chamber (S121), supplying microwaves to the chamber to form a first plasma (S122), and supplying a second process gas into the chamber to form a second plasma (S123).

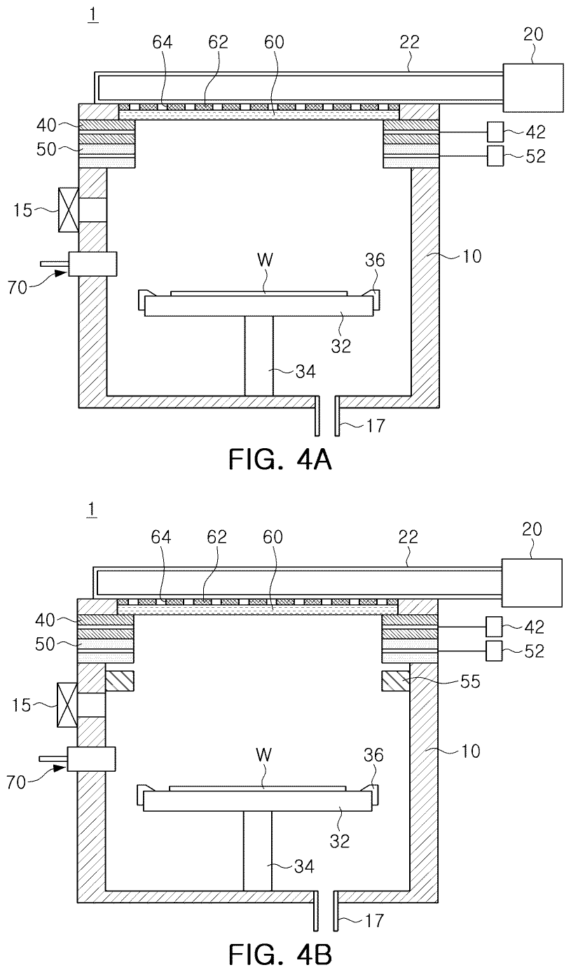

FIG. 4A is a cross-sectional view of a plasma processing device according to an example embodiment. FIG. 4A illustrates a plasma processing device including a chamber in which the method (S120) for removing the residue 145 is performed.

Referring to FIG. 4A, a plasma processing device 1 may include a chamber 10 and a microwave generating device 20 connected to the chamber 10 and supplying microwaves to the chamber 10. The chamber 10 may include side walls that define an internal space of the chamber 10.

The chamber 10 may include a metal material such as aluminum (Al). In an example embodiment, the chamber 10 may include a wafer transfer port 15, and the wafer transfer port 15 may be disposed on (and may extend through) a side wall of the chamber 10 so that a semiconductor wafer W may be loaded or unloaded through the wafer transfer port 15. The wafer transfer port 15 may be coupled to a transfer chamber of another semiconductor wafer processing device and/or other chambers of the plasma processing device 1. The semiconductor wafer W may include a substrate 110 described with reference to FIGS. 2A to 2F.

The chamber 10 may include an exhaust pipe 17 connected to a wall of a lower portion thereof. The exhaust pipe 17 may be connected to a vacuum pump. The exhaust pipe 17 may exhaust process gases, process byproducts, and the like, in the chamber 10, and may be used to control the pressure in the chamber 10.

The chamber 10 may include an electrostatic chuck 32 to support a semiconductor wafer W and a lower supporter 34 supporting the electrostatic chuck 32. The lower supporter 34 may vertically raise or lower the electrostatic chuck 32. The electrostatic chuck 32 and the lower supporter 34 may be disposed in a lower portion of the chamber 10.

The electrostatic chuck 32 may be a susceptor including a heating member (e.g., a heater or heating device), and the heating member may be disposed in the susceptor. The heating member may be provided with power from the outside of the chamber 10 or the outside of the susceptor to heat the susceptor. The susceptor may include a ceramic material, such as aluminum nitride (AlN), aluminum oxide (Al₂O₃), or the like. In an example embodiment, the electrostatic chuck 32 may include an electrode inside, and the electrode may be connected to a high-frequency power source. The electrode may apply a bias voltage to the semiconductor wafer W.

The chamber 10 may include a guide ring 36 extending along an outer periphery of the electrostatic chuck 32 to guide the semiconductor wafer W.

The chamber 10 may further include an upper gas ring 40 and a lower gas ring 50 disposed in an upper portion of the chamber 10. The upper gas ring 40 and the lower gas ring 50 may be disposed on the semiconductor wafer W and the electrostatic chuck 32. The upper gas ring 40 and the lower gas ring 50 may extend in a circumferential direction along the side wall of the chamber 10. The upper gas ring 40 may be connected to an upper gas supply device 42, and may supply a process gas into the chamber 10. For example, the upper gas ring 40 may supply at least one of Ar, H₂, CO₂, O₂, NH₃, and He into the chamber 10.

The lower gas ring 50 may be disposed below the upper gas ring 40. The lower gas ring 50 may be connected to a lower gas supply device 52 and may supply a process gas into the chamber 10. For example, the lower gas ring 50 may supply at least one of DCS, N₂, CH₄, H₂, HCl, He, or Ar into the chamber 10.

The chamber 10 may further include a dielectric plate 60 and a planar antenna 62 disposed on the upper gas ring 40.

The dielectric plate 60 may be formed of a dielectric. The dielectric plate 60 may be disposed on the upper gas ring 40, and a lower surface of the dielectric plate 60 may be exposed to an internal space of the chamber 10. Microwaves transmitted through the dielectric plate 60 may be supplied to the process gas supplied to the chamber by the upper gas ring 40, and may generate surface wave plasma in a portion directly below the dielectric plate 60 in the chamber 10.

The planar antenna 62 may be disposed on the dielectric plate 60. The planar antenna 62 may be connected to a waveguide 22, and may radiate microwaves to the dielectric plate 60. The planar antenna 62 may include portions defining a plurality of slots 64 for uniformly radiating microwaves.

The plasma processing device 1 may further include an analyzer 70 on the side wall of the chamber 10. The analyzer 70 may be an Optical Emission Spectroscopy (OES) device. The OES device may receive light from outside the chamber 10 to analyze the uniformity of plasma in the chamber, plasma stability, and substances within the plasma.

FIG. 4B is a cross-sectional view of a plasma processing device according to an example embodiment.

Referring to FIG. 4B, the plasma processing device 1 may further include an electrode ring 55 disposed in the chamber 10. The electrode ring 55 may be disposed between the lower gas ring 50 and the semiconductor wafer W. For example, the electrode ring 55 may extend in a horizontal direction along the side wall of the chamber 10.

The electrode ring 55 may be connected to a power source outside the chamber 10, and voltage may be applied to the electrode ring 55. In an example embodiment, the electrode ring 55 may apply an electric field to the second plasma P2 described below, and may improve plasma uniformity. Accordingly, the second plasma P2 may be uniformly provided on the semiconductor wafer W.

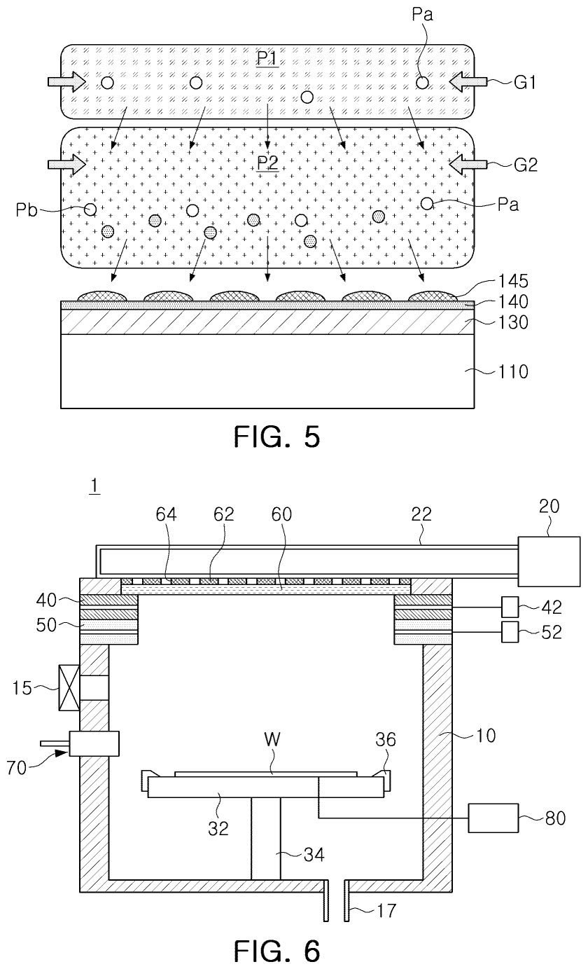

FIG. 5 is a conceptual diagram illustrating a method of removing a residue according to an example embodiment. Hereinafter, the method of removing a residue will be explained with reference to FIGS. 3 to 5.

Referring to FIGS. 3 to 5, a first process gas G1 may be supplied to the chamber 10 (S121). The first process gas G1 may be supplied by the upper gas ring 40. For example, the upper gas supply device 42 may supply the first process gas G1 to the upper gas ring 40. The first process gas G1 may include at least one of Ar, H₂, CO₂, O₂, NH₃, or He. For example, the first process gas G1 may include Ar and He.

Then, microwaves may be supplied to the chamber 10 to form a first plasma P1 (S122). For example, the microwaves generated from the microwave generating device 20 may be transmitted to the planar antenna 62 disposed in the upper portion of the chamber 10 through the waveguide 22. The planar antenna 62 may evenly radiate the microwaves to the dielectric plate 60. The microwaves may be transmitted to the dielectric plate 60 to ionize the first process gas G1, and the first plasma P1 may be formed below the dielectric plate 60. The first plasma P1 may include, for example, Ar ions, He ions, and electrons (illustrated as Pa).

After the first plasma P1 is formed, a second process gas G2 may be supplied to the chamber 10 to form a second plasma P2 (S123). The second process gas G2 may be supplied by the lower gas ring 50. For example, the lower gas supply device 52 may supply the second process gas G2 to the lower gas ring 50. The second process gas G2 may be injected below the first plasma P1 (i.e., between the two-dimensional material layer 140 and the first plasma P1). The second process gas G2 may include a different material (illustrated as Pb) from the first process gas G1. The second process gas G2 may include at least one of Dichlorosilane (DCS), N₂, CH₄, H₂, HCl, He, or Ar. For example, the second process gas G2 may include hydrogen (H₂), helium (He), and argon (Ar). The second process gas G2 may include an inert gas such as Ar or He, and a flow rate ratio of the inert gas and the hydrogen gas of the second process gas G2 may be 1:n (n is 1 to 10).

The second process gas G2 may react with electrons formed from the first plasma P1, and the second plasma P2 may be formed. The second plasma P2 may include an etchant, and the etchant may include, for example, hydrogen radicals. The hydrogen radicals may remove the residue 145 from the surface of the two-dimensional material layer 140. The hydrogen radicals may remove carbon-containing residues 145 by physical and/or chemical methods. Operations S121, S122 and S123 may be performed in a range of about 5 seconds to about 60 seconds, respectively. As described with reference to FIG. 4B, the electrode ring 55 may apply an electric field to the second plasma P2. Accordingly, the hydrogen radicals may be uniformly supplied across the entire semiconductor wafer W by the electric field.

Among plasma generation methods, there are provided a capacitively coupled plasma (CCP) method and an inductively coupled plasma (ICP) method depending on an RF power application method. The capacitively coupled method and the inductively coupled method may form high-density plasma in the chamber and apply excessive ion bombardment to an inner wall of the chamber or the substrate. Additionally, in the plasma formed by the inductively coupled method, it may be difficult to form and maintain a uniform plasma. Additionally, a remote plasma source (RPS) method for forming plasma outside the chamber in which processes such as deposition and etching are performed and supplying the plasma or components of the plasma into the chamber may find it difficult to uniformly supply radicals onto the substrate.

According to example embodiments, the first plasma P1 and the second plasma P2 may be formed in the chamber 10, and because the first plasma P1 and the second plasma P2 are surface wave plasmas, the first plasma P1 and the second plasma P2 may reduce damage to the substrate 110 or the two-dimensional material layer 140 on the substrate 110. For example, the first plasma P1 may be a high-density plasma with a high electron temperature, and the second plasma P2 may be a low-density plasma. Accordingly, hydrogen radicals included in the second plasma P2 may reduce damage to the two-dimensional material layer 140. For example, a volume change of the two-dimensional material layer 140 due to a removal process (S120) of the residue 145 may be about 5.4%. Accordingly, it may be possible to prevent the deterioration of the electrical characteristics of the thin film, such as an increase in the contact resistance of the two-dimensional material layer 140 due to damage to the two-dimensional material layer 140 and a voltage drop due to the contact resistance.

Additionally, as compared to the RPS method, the method of removing the residue 145 according to example embodiments may form plasmas P1 and P2 in the chamber 10, so that the hydrogen radicals may be effectively transmitted onto the two-dimensional material layer 140 and the process time may be shortened.

In the case of performing high-temperature treatment to remove the residue 145 such as carbon impurities, there may be a concern that sulfur vacancy defects may occur in the two-dimensional material layer 140 such as MoS₂. However, because the method of removing the residue 145 is performed at a relatively low temperature, it may be possible to prevent the sulfur vacancy defects and the deterioration of thin film properties of the two-dimensional material layer 140. For example, the process may be performed in a range of about 100 degrees Celsius to about 250 degrees Celsius.

A flow rate of the second process gas G2 supplied to the chamber 10 may be in the range of about 10 standard cubic centimeters per minute (SCCM) to about 500 SCCM. In an example embodiment, the pressure in the chamber 10 may be in the range of about 10 mTorr to about 500 mTorr. In an example embodiment, the pressure in the chamber 10 may be in the range of about 50 mTorr to about 100 mTorr. According to example embodiments, on the substrate 110, for example, on the two-dimensional material layer 140, an electron temperature may be greater than 0 and less than about 2 eV. Accordingly, the residue 145 may be removed without damaging the two-dimensional material layer 140. The ion density of the second plasma P2 may be greater than 0 and less than about 10×10¹⁰/cm³.

FIG. 6 is a cross-sectional view of a plasma processing device according to an example embodiment.

Referring to FIG. 6, the plasma processing device 1 may further include a sensor 80. The sensor 80 may include a probe connected to the substrate 110 and may measure ion density and electron temperature on the substrate 110. Hereinafter, results of measuring plasma and electron temperature in the removal process (S120) of the residue 145 using the analyzer 70 and the sensor 80 will be described.

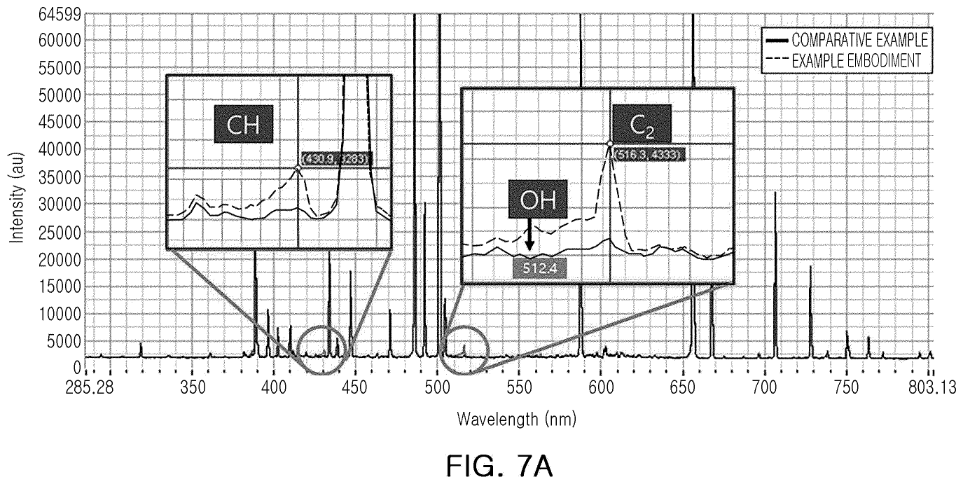

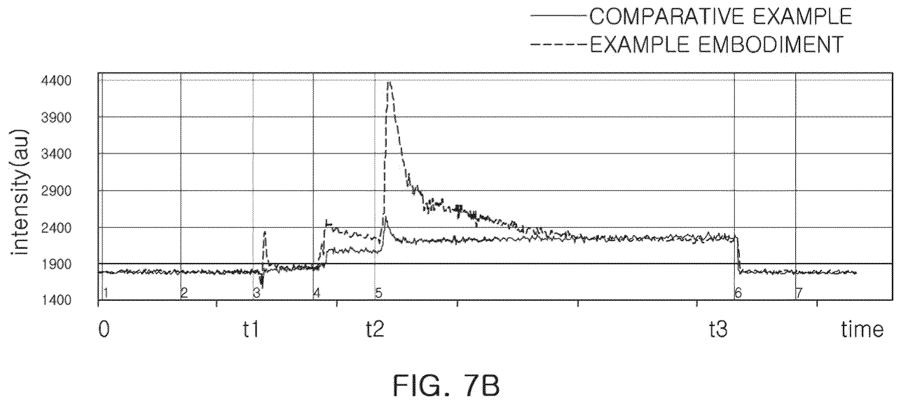

FIG. 7A and FIG. 7B illustrate results of OES analysis. As described above, the OES analyzer 70 measures substances in the chamber 10, such as plasma. For example, the OES analyzer 70 measures substances removed from a surface of the two-dimensional material layer 140 by the removal process (S120) of the residue 145 and scattered into the chamber 10, rather than the residue 145 attached to the surface of the two-dimensional material layer 140.

FIG. 7A illustrates the results of detecting a substance in plasma in Comparative Example 1 and example embodiments. Referring to FIG. 7A, in Comparative Example 1, plasma was formed on a silicon wafer on which deposition and etching processes were not performed, and analysis was performed on the plasma. In example embodiments, analysis was performed on the first and second plasmas P1 and P2 described in FIGS. 3 to 5. As illustrated in FIG. 7A, a high peak was observed at a wavelength corresponding to carbon (C₂). Accordingly, as illustrated in FIG. 7B, the wavelength corresponding to carbon (C₂) was measured over time to measure carbon impurities included in the residue 145.

Referring to FIG. 7B, the first plasma P1 was formed at t1. It was observed that the residue 145 on the two-dimensional material layer 140 was partially removed by ions, electrons, and radicals included in the first plasma P1. Then, the second plasma P2 was formed from t2 to t3, and an etchant such as hydrogen radicals was supplied onto the two-dimensional material layer 140. As illustrated in FIG. 7B, a larger amount of carbon (C₂) was observed in example embodiments than in Comparative Example 1, so that it may be seen that a relatively large amount of residue 145 was removed in example embodiments.

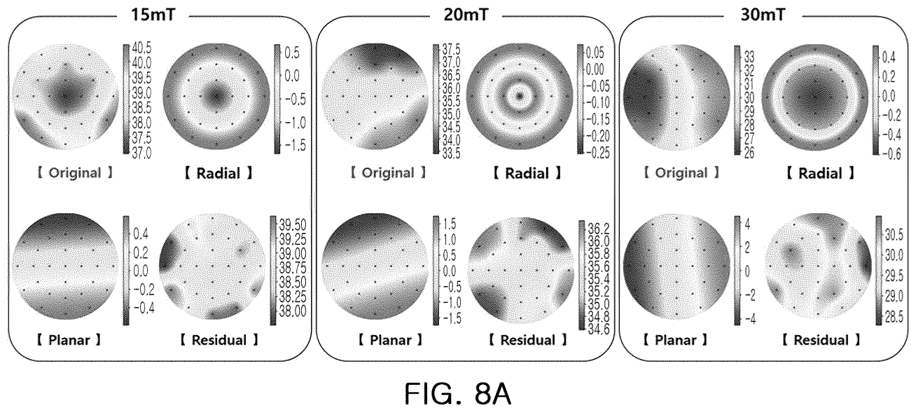

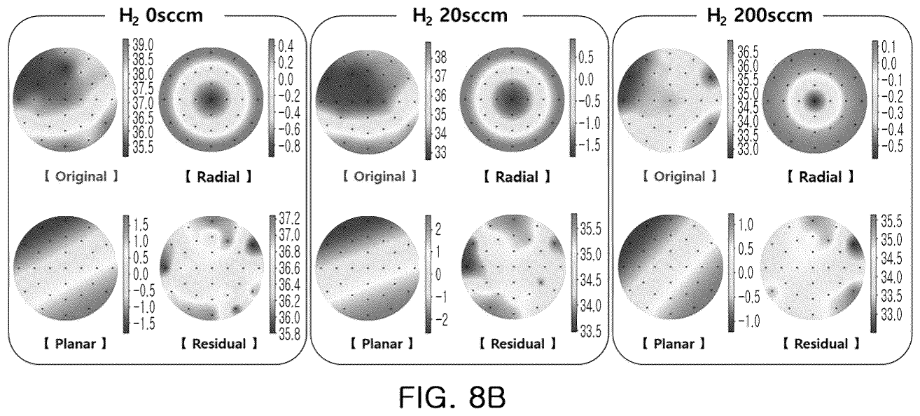

FIG. 8A illustrates a wafer map according to pressure change. FIG. 8B illustrates a wafer map according to a flow rate change. The wafer map illustrates the distribution of ion density on the semiconductor wafer W. ‘Radial’ shows a distribution pattern in a radial direction of ion density, ‘planar’ shows an asymmetrical distribution pattern of ion density, and ‘residual’ shows a remaining distribution pattern excluding ‘radial’ and ‘planar.’ ‘Original’ shows a distribution pattern reflecting all of ‘radial,’ ‘planar’ and ‘residual.’ An electron temperature in all regions on the wafer is less than 2 eV.

Referring to FIGS. 8A and 8B, it was observed that as the pressure in the chamber 10 increased and the flow rate in the chamber 10 increased, the electron temperature decreased and the radial dispersion decreased. Here, the flow rate may refer to the sum of flow rates of process gases provided in the chamber 10.

TABLE 1

| | Average ion density | Average electron |
|---|---|---|
| Pressure (mTorr) | (10¹⁰/cm³) | temperature (eV) |
| 15 | 38.6 | 10.42 |
| 20 | 35.4 | 9.12 |
| 30 | 29.8 | 6.99 |

Table 1 shows the ion density and electron temperature according to the pressure in the chamber 10. Referring to Table 1, as the pressure inside the chamber 10 increased, the ion density and electron temperature decreased. Specifically, when the pressure was 15 mTorr, the ion density (the number of ions per unit volume) was 36.9×10¹⁰/cm³ to 40.55×10¹⁰/cm³, and an average was 38.6×10¹⁰ cm³. The electron temperature was 9.89 eV to 11.31 eV, and an average was 10.42 eV. When the pressure was 20 mTorr, the ion density was 33.4×10¹⁰/cm³ to 37.7×10¹⁰/cm³, and an average was 35.4×10¹⁰/cm³. The electron temperature was 8.19 eV to 10.03 eV, and an average was 9.12 eV. When the pressure is 30 mTorr, the ion density was 25.7×10¹⁰/cm³ to 33.86×10¹⁰/cm³, and an average was 29.8×10¹⁰/cm³. The electron temperature was 5.57 eV to 8.49 eV, and an average was 6.99 eV.

TABLE 2

| | Ion density | Electron |
|---|---|---|
| Flow rate (SCCM) | (10¹⁰/cm³) | temperature (eV) |
| 15 | 36.6 | 9.50 |
| 20 | 34.8 | 8.81 |
| 30 | 34.3 | 8.70 |

Table 2 shows the ion density and electron temperature according to the flow rate inside the chamber 10. Referring to Table 2, as the flow rate of the process gas in the chamber 10 increased, the ion density and electron temperature decreased. Specifically, when the flow rate was 0 SCMM, the ion density was 35.1×10¹⁰/cm³ to 39.2×10¹⁰/cm³, and an average was 36.6×10¹⁰/cm³. The electron temperature was 8.81 eV to 10.5 eV, and an average was 9.50 eV. When the flow rate was 20 SCCM, the ion density was 32.6×10¹⁰/cm³ to 38.9×10¹⁰/cm³, and an average was 34.8×10¹⁰/cm³. The electron temperature was 7.92 eV to 10.44 eV, and an average was 8.81 eV. When the flow rate was 200 SCCM, the ion density was 32.7×10¹⁰/cm³ to 37.0×10¹⁰/cm³, and an average was 34.3×10¹⁰/cm³. The electron temperature was 8.02 eV to 9.73 eV, and the average was 8.70 eV.

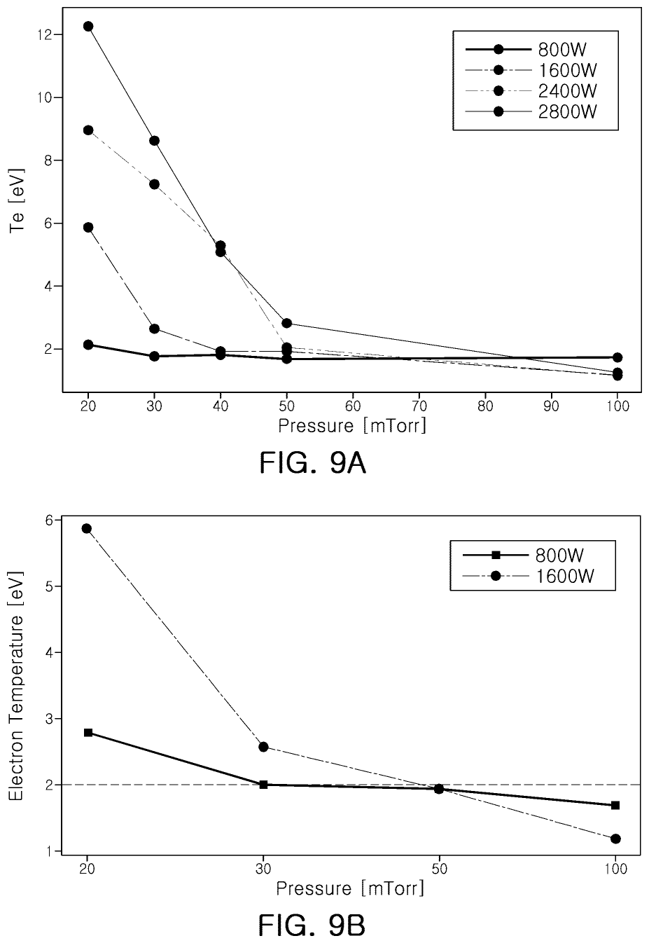

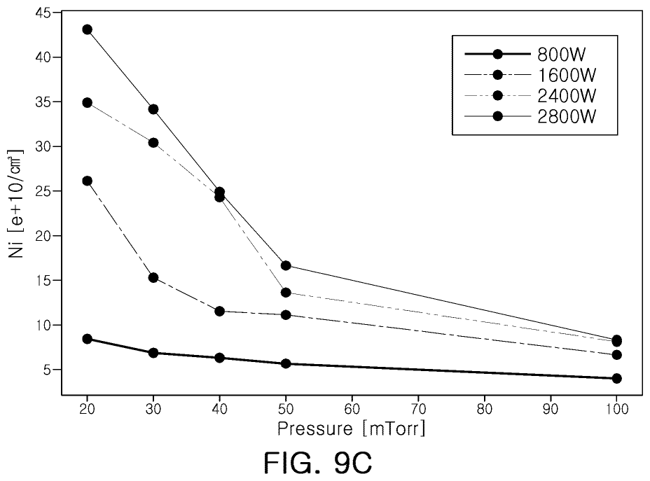

FIGS. 9A to 9C illustrate results of measuring the electron temperature and the results of measuring the ion density. FIGS. 9A and 9B illustrate a change in the electron temperature according to the pressure depending on the output of the microwaves. FIG. 9C illustrates the ion density according to the pressure depending on the output of the microwaves.

Referring to FIGS. 9A and 9B, the electron temperature decreases as the pressure inside the chamber 10 increases. For example, as the pressure increases, the electron temperature decreases below 2 eV. At an electron temperature of about 2 eV or less, the residue 145 may be effectively removed without damaging the two-dimensional material layer 140. Additionally, it was observed that the electron temperature decreased as the output of the microwave increased.

Referring to FIG. 9C, the ion density decreases as the pressure in the chamber 10 increases. For example, as the pressure increases, the ion density becomes lower than 10 eV. At an ion density of about 10×10¹⁰/cm³ or less, the residue 145 may be effectively removed without damaging the two-dimensional material layer 140. Additionally, it was observed that the ion density decreased as the output of the microwaves increased.

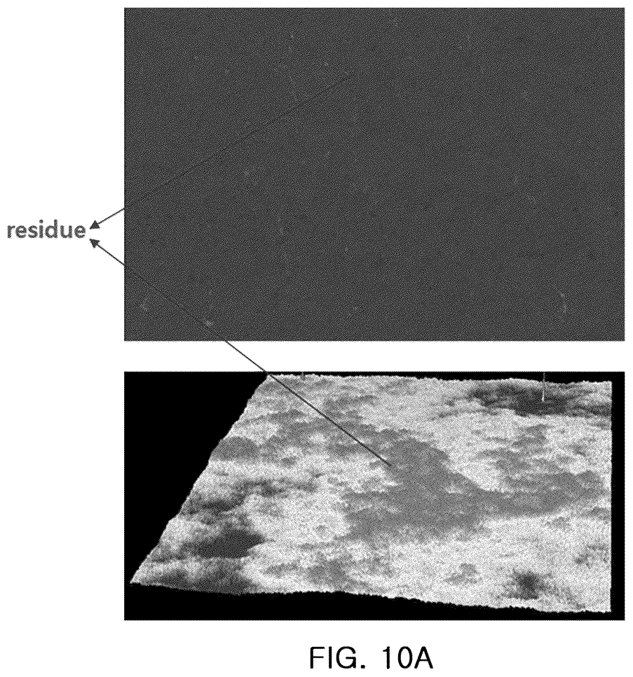

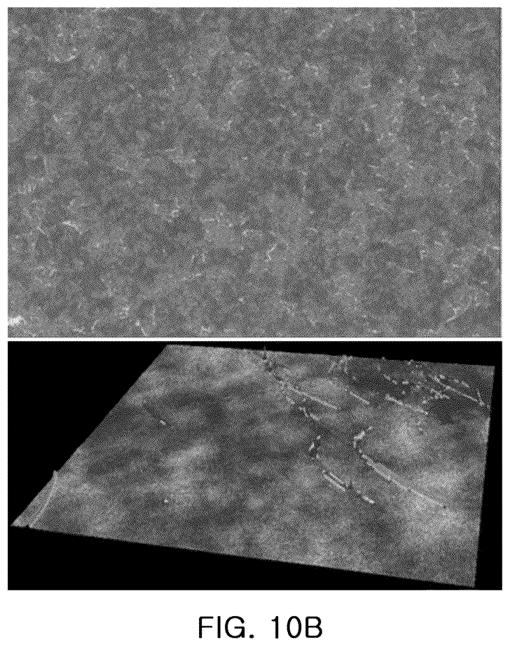

FIGS. 10A and 10B illustrate a surface of a two-dimensional material according to a comparative example and example embodiments. FIG. 10A illustrates a two-dimensional material layer according to a comparative example, and FIG. 10B illustrates a two-dimensional material layer according to an example embodiment. Upper portions of FIGS. 10A and 10B illustrate a surface of the two-dimensional material layer captured with a scanning electron microscope (SEM). Lower portions of FIGS. 10A and 10B illustrate a surface of the two-dimensional material layer captured with a phase shifting interferometer.

Referring to FIG. 10A, when the removal process (S120) of the residue was not performed in Comparative Example 2, it was observed that the two-dimensional material layer was covered with the residue. Referring to FIG. 10B, the residue was removed by the removal process (S120) of the residue, and one or two two-dimensional material layers were observed.

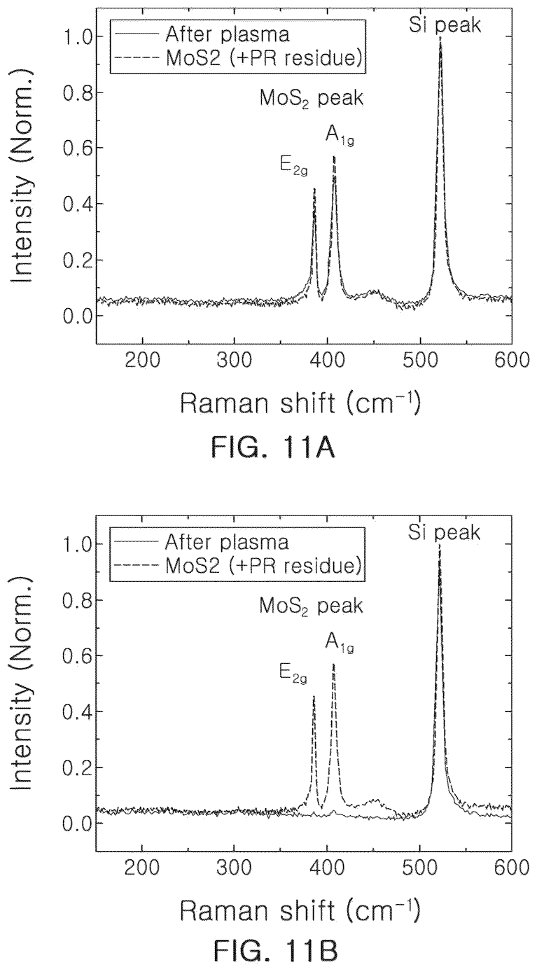

FIGS. 11A and 11B illustrate Raman spectra of the two-dimensional material layers according to example embodiments and a comparative example. Specifically, FIG. 11A illustrates results of Raman spectrum analysis of the two-dimensional material layer in example embodiments, and FIG. 11B illustrates results of Raman spectrum analysis of the two-dimensional material layer in the comparative example. E_{2g} represents a peak of MoS₂ in an in-plane mode, and A_{1g} represents a peak of MoS₂ in an out-of-plane mode. An Si peak represents silicon included in the substrate.

Referring to FIG. 11A, according to example embodiments, it was observed that the peak of MoS₂ barely changed before and after performing the removal process (S120) of the residue. In example embodiments, the removal process (S120) of the residue was performed in a range in which the electron temperature on the surface of the two-dimensional material layer was less than 2 eV. A volume change of the two-dimensional material layer, MoS₂, due to the removal process (S120) of the residue, was within about 5.4%. That is, damage to MoS₂ may be prevented during the removal process (S120) of the residue.

Referring to FIG. 11B, it was observed that a peak change of MoS₂ was relatively large before and after performing the removal process (S120) of the residue in Comparative Example 3. In Comparative Example 3, the electron temperature on the surface of the two-dimensional material layer was performed in a range in which the removal process (S120) of the residue was greater than 2 eV. In contrast to FIG. 11A, it was observed that significant damage to MoS₂ occurred in Comparative Example 3.

While aspects of example embodiments have been particularly shown and described, it will be understood that various changes in form and details may be made therein without departing from the spirit and scope of the following claims.

What is claimed is:

1. A method of manufacturing a semiconductor device, the method comprising:
providing a two-dimensional material layer on a substrate; and
supplying an etchant to the two-dimensional material layer to remove a residue from the two-dimensional material layer,
wherein the supplying the etchant to the two-dimensional material layer comprises:
supplying a first process gas to a chamber in which the substrate is provided;
supplying microwaves to the chamber to form a first plasma in the chamber; and
supplying a second process gas, including a different material from the first process gas, to the chamber to form a second plasma including the etchant.

2. The method of claim 1, wherein the two-dimensional material layer includes a transition metal and a chalcogen element.

3. The method of claim 1, wherein the supplying the first process gas comprises controlling an upper gas ring to supply the first process gas, and
wherein the upper gas ring is provided in the chamber on the substrate.

4. The method of claim 3, wherein the supplying the second process gas comprises controlling a lower gas ring to supply the second process gas, and
wherein the lower gas ring is provided in the chamber between the substrate and the upper gas ring.

5. The method of claim 4, further comprising controlling an electrode ring to apply an electric field to the second plasma,
wherein the electrode ring is provided in the chamber between the lower gas ring and the substrate.

6. The method of claim 3, further comprising:
controlling a microwave generating device outside the chamber to generate the microwaves; and
transmitting the microwaves to a dielectric plate on the upper gas ring.

7. The method of claim 1, wherein the second plasma is formed by electrons of the first plasma reacting with the second process gas.

8. The method of claim 1, wherein the first process gas includes at least one of Ar, H₂, CO₂, O₂, NH₃, or He.

9. The method of claim 1, wherein the second process gas includes at least one of DCS, N₂, CH₄, H₂, HCl, He, or Ar.

10. The method of claim 1, wherein the second plasma is supplied onto the two-dimensional material layer to remove the residue.

11. The method of claim 1, wherein an electron temperature of the second plasma on a surface of the two-dimensional material layer is greater than 0 and less than 2 eV while the second process gas is supplied to the chamber.

12. The method of claim 1, wherein a flow rate of the second process gas is between 10 standard cubic centimeters per minute (SCCM) and 500 SCCM.

13. The method of claim 1, wherein pressure in the chamber is between 10 mTorr and 500 mTorr while the second process gas is supplied to the chamber.

14. The method of claim 1, wherein a temperature in the chamber ranges is between 100 degrees Celsius and 250 degrees Celsius while the second process gas is supplied to the chamber.

15. The method of claim 1, wherein each of processes of supplying the first process gas into the chamber, supplying the microwaves into the chamber, and supplying the second process gas into the chamber are performed for at least 5 seconds and no more than 60 seconds.

16. The method of claim 1, wherein an amount of change in the two-dimensional material layer due to a removal process of the residue is 5.4% or less.

17. A method of manufacturing a semiconductor device, the method comprising:
providing a two-dimensional material layer on a substrate;
forming a mask layer on the two-dimensional material layer, wherein the mask layer exposes a first region and a second region of the two-dimensional material layer;
forming a first source/drain electrode on the first region and a second source/drain electrode on the second region;
removing the mask layer to expose a third region of the two-dimensional material layer between the first region and the second region; and
removing a residue on the third region of the two-dimensional material layer,
wherein the removing the residue comprises:
supplying a first process gas to a chamber in which the substrate is provided;
supplying microwaves to the chamber to form a first plasma in the chamber; and
supplying a second process gas, including a different material from the first process gas, to the chamber to form a second plasma.

18. The method of manufacturing a semiconductor of claim 17, further comprising forming a gate dielectric layer and a gate electrode on the third region.

19. The method of manufacturing a semiconductor of claim 17, further comprising:
forming a back gate electrode on the substrate; and
forming the two-dimensional material layer on the back gate electrode.

20. A method of manufacturing a semiconductor device, the method comprising:
providing a two-dimensional material layer on a substrate; and
supplying an etchant to the two-dimensional material layer to remove a residue from the two-dimensional material layer,
wherein the supplying the etchant to the two-dimensional material layer comprises:
supplying a first process gas to a chamber in which the substrate is provided;
supplying microwaves to the chamber to form a first plasma in the chamber; and
supplying a second process gas, including a different material from the first process gas, to the chamber to form a second plasma,
wherein the second process gas includes hydrogen,
wherein the second plasma includes the etchant, and the etchant includes hydrogen radicals, and
wherein the residue is removed from a surface of the two-dimensional material layer by the hydrogen radicals.
